(19) United States
(12) Patent Application Publication
(10) Pub. No.: US 2017/0268502 A1
(43) Pub. Date: Sep. 21, 2017

(54) PUMP AND APPARATUS FOR SUPPLYING LIQUID

(71) Applicant: SEMES CO., LTD., Chungcheongnam-do (KR)

(72) Inventors: Moon Soon Choi, Chungcheongnam-do (KR); Seok Gyu Kim, Seoul (KR); Youngju Jeong, Chungcheongnam-do (KR)

(21) Appl. No.: 15/457,031

(22) Filed: Mar. 13, 2017

(30) Foreign Application Priority Data
Mar. 16, 2016 (KR) 10-2016-0031304

(51) Int. Cl. F04B 53/08; F04B 53/00; F04B 53/06; B08B 3/02; H01L 21/67; B08B 3/08; B08B 3/04; F04B 43/10; F04B 23/02

(52) U.S. Cl. CPC F04B 53/08; F04B 43/10; F04B 53/002; F04B 53/06; F04B 23/02; H01L 21/67023; B08B 3/08; B08B 3/041; B08B 3/022

(57) ABSTRACT

A pump is disclosed which includes a pump body, a silencer connected to the pump body, and a condensation preventing device surrounding the silencer. A liquid supplying apparatus is also disclosed which includes the pump for providing a power to supply the liquid to outside, and a storage tank for storing a liquid.

### CROSS-REFERENCE TO RELATED APPLICATIONS

A claim for priority under 35 U.S.C. §119 is made to Korean Patent Application No. 10-2016-0031304 filed on Mar. 16, 2016 in the Korean Intellectual Property Office, the entire contents of which are hereby incorporated by reference.

### BACKGROUND OF THE INVENTION

This disclosure relates to a pump and apparatus for supplying liquid to prevent freezing or condensation of a silencer.

Containments like a particle, an organic containment, a metal containment, etc. residing in a substrate surface highly influences a production yield and the device's characteristics. Therefore, a cleaning process removing different kinds of containments attached to the substrate surface is issued as an important process during a semiconductor manufacturing process, and cleaning the substrate is performed before and after each unit process of a semiconductor manufacturing process.

Meanwhile, the cleaning process uses chemical such as a chemical liquid. A pump used in chemical liquid supplying apparatus may be a bellows type using air pressure. This kind of pump has serious exhaust sound generated in a vent unit. Therefore, generally a silencer is installed in the vent unit.

FIG. 1 illustrates a conventionally used pump 1. In a vent unit 2 of the pump, a silencer 3 to reduce a noise is installed. A several holes 4 are formed in a surface of the silencer 3. Also, for its true effect the silencer 3 has specification such as material, thickness, size and numbers of holes. An air pumped in the pump 1 goes into the silencer 3 and comes outside through several holes 4. The air came out of the holes 4 adiabatically expands and absorbs air. A surface of the silencer 3 is cooled thereby condensation or freezing happens. This kind of phenomenon blocks holes 4 of the silencer 3 and disturbs exhausting an air. This causes trouble in operation and process of the silencer 3.

### SUMMARY OF THE INVENTION

An embodiment includes a pump to prevent freezing or condensation in a surface of a silencer.

An embodiment includes a liquid supplying apparatus to prevent poor operation of a pump silencer and poor processing therein.

Embodiments of present invention are not limited to hereinafter, and other objects thereof will be understandable by those skilled in the art from the following descriptions.

Example embodiments of the inventive concept may provide a pump.

In example embodiment, the pump comprises: a pump body; a silencer connected to the pump body; and a condensation preventing device surrounding the silencer.

In example embodiment, the condensation preventing device comprises a housing surrounding the silencer. A plurality of vent holes for exhausting air is formed in the housing.

In example embodiment, the housing is spaced apart from the silencer surrounds the silencer.

In example embodiment, a plurality of exhaust holes is formed in a surface of the silencer.

In example embodiment, the plurality of vent holes is formed in a lateral side of the housing and is opposed to the plurality of exhaust holes.

In example embodiment, the vent is bigger than the hole.

In example embodiment, the housing is provided with a resin material.

In example embodiment, the surface of the silencer is provided with a mesh structure.

Example embodiments of the inventive concept may provide a liquid supplying apparatus.

In example embodiment, the liquid supplying apparatus comprises: a storage tank for storing a liquid; and a pump for providing a power to supply the liquid to outside. The pump comprises: a pump body; a silencer connected to the pump body; and a condensation preventing device surrounding the silencer.

In example embodiment, the condensation preventing device comprises a housing surrounding the silencer. A plurality of vent holes for exhausting air is formed in the housing.

In example embodiment, the housing is spaced apart from the silencer surrounds the silencer.

In example embodiment, a plurality of exhaust holes is formed in a surface of the silencer.

In example embodiment, the plurality of vent holes is formed in a lateral side of the housing and is opposed to the plurality of exhaust holes.

According to an example embodiment, a condensation or freezing in a surface of a silencer may be prevented.

According to an example embodiment, poor operation of a pump silencer and poor processing therein may be prevented.

### BRIEF DESCRIPTION OF THE DRAWINGS

FIG. 1 roughly illustrates a prior substrate treating apparatus for cleaning a substrate using a cleaning medium.

FIG. 2 is a plan view roughly illustrating a substrate treating apparatus.

FIG. 3 roughly illustrates a substrate treating apparatus including a liquid supplying apparatus according to an embodiment.

FIG. 4 illustrates a liquid supplying apparatus according to an embodiment.

FIGS. 5 and 6 are illustrating a silencer of a pump according to an embodiment.

FIG. 7 illustrates a housing of a pump according to an embodiment.

FIG. 8 illustrates an air flow from a pump according to an embodiment.

### DETAILED DESCRIPTION

Various example embodiments will be described more fully hereinafter with reference to the accompanying drawings, in which some example embodiments are shown. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Therefore, features of the drawings are exaggerated to emphasize definite explanation.

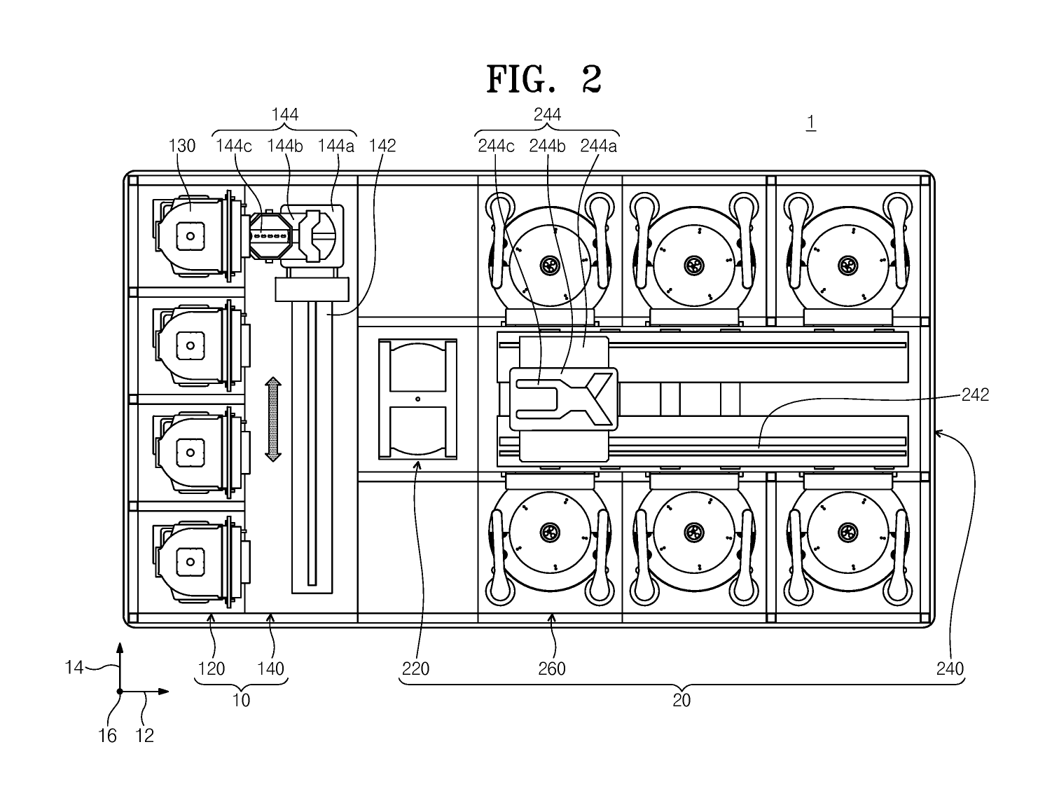

Hereinafter explain an example embodiments referring to FIGS. 2 to 8.

FIG. 2 is a plan view roughly illustrating a substrate treating apparatus 1.

Referring to FIG. 2, a substrate treating apparatus 1 includes an index module 100 and a process treating module 200. The index module 100 includes a load port 120 and a transfer frame 140. The load port 120, the transfer frame 140, and the process treating module 200 are sequentially arranged in a row. Hereinafter, a direction where the load port 120, the transfer frame 140, and the process treating module 200 are arranged is referred to as a first direction 12. And a direction perpendicular to the first direction 12 is referred to as a second direction 14, when view from a top side, and a direction perpendicular to a plane including the first direction 12 and the second direction 14 is referred to as a third direction 16.

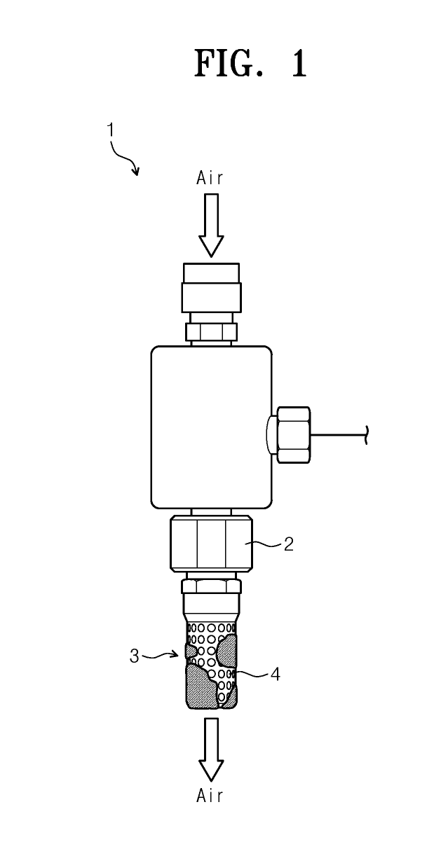

A carrier 130 where a substrate W is stored is seated on the load port 120. The load port 120 is provided as a plurality of numbers and they are arranged in a row along the second direction 14. In the FIG. 1, it described that four load ports 120 are provided. However, the number of load ports 120 may be increased or decreased depending on a requirement like process efficiency and a footprint of the process treating module 200. In the carrier 130, a plurality of slots (not described) are provided to support an edge of the substrate W. A plurality of slots are provided along the third direction 16 and a plurality of substrates W is placed inside the carrier vertically stacked to each other along the third direction 16. A front opening unified pod (FOUP) may be used as the carrier 130.

The process treating module 200 includes a buffer unit 220, a transfer chamber 240, and a process chamber 260. The transfer chamber 240 is provided such that the lengthwise direction thereof is parallel with the first direction 12. The process chambers 260 are provided in one side and the other side of the transfer chamber 240 along the second direction 14, respectively. The process chambers 250 are provided symmetrically in one and the other sides of the transfer chamber 240. Some of the process chambers 260 are placed along the lengthwise direction of the transfer chamber 240. Also, some of the process chambers 260 are placed vertically stacked to each other. That is, in one side of the transfer chamber 240, the process chambers 260 may be arranged in A×B (A and B are natural number of 1 or above) array. Herein, A is the number of the process chambers 250 which are provided along the first direction 12, and B is the number of process chambers 260 which are provided along the third direction 16. When four or six process chambers 260 are provided on one side of the transfer chamber 240, the process chambers 260 may be arranged in 2×2 or 3×2 arrays. The number of the process chamber 260 may be increased or decreased. Unlike described above, the process chamber 260 may be provided only on one side of the transfer chamber 240. Also, unlike described above, the process chamber 260 may be provided as a single layer at both sides of the transfer chamber 240.

The buffer unit 220 is arranged between the transfer frame 140 and the transfer chamber 240. The buffer unit provides a space for the substrate W to stay temporarily before transferring the substrate W between the transfer chamber 240 and the transfer frame 140. The slot (not described) where the substrate places is provided inside (e.g., inner wall) of the buffer unit 220, and the slots (not described) are provided with a plurality of numbers spaced apart from each other along the third direction 16. One side of the buffer unit 220 facing the transfer frame 140, and the other side of the buffer unit 220 facing the transfer chamber 240 are opened.

The transfer frame 140 transfers the substrate W between the buffer unit 220 and the carrier 130 seated on the load port 120. In the transfer frame 140, an index rail 142 and an index robot 144 are provided. The index rail 142 is provided such that the lengthwise direction is parallel to the second direction 14. The index robot 144 is installed on the index rail 142, and move linearly along the index rail 142 to the second direction 14. The index robot 144 includes a base 144a, a body 144b, and an index arm 144c. The base 133a is installed movably along the index rail 142. The body 144b is coupled to the base 144a. The body 144b is provided movably along the third direction 16 on the base 144a. Also, the body 144b is provided rotatable on the base 144a. The index arm 144c is coupled to the body 144b, and is provided to move front and back to the body 144b. The index arm 144c is provided with a plurality of numbers and they are driven independently. The index arms 144c are arranged vertically, i.e., spaced apart from each other along the third direction 16. Some of the index arms 144c may be used when transferring the substrate W from the process treating module 200 to the carrier 130, and some may be used when transferring the substrate W from the carrier 130 to the process treating module 200. In this way, during the index robot 144 carries in or carries out the substrate W, particles that have come from a substrate before treating process may be prevented from adhering to a substrate after treating process.

The transfer chamber 240 transfers the substrate W between process chambers 260 and the buffer unit 220 and between the process chambers 260. A guide rail 242 and a main robot 244 are provided in the transfer chamber 240. The guide rail 242 is places such that the lengthwise direction is parallel with the first direction 12. The main robot 244 is installed on the guide rail 242, and moves linearly along the first direction 12 on the guide rail 242. The main robot 244 includes a base 244a, a body 244b, and a main arm 244c. The base 244a is installed movably along the guide rail 242. The body 244b is coupled to the base 244a. The body 244b is provided movably along the third direction 16 on the base 244a. Also, the body 244b is provided rotatable on the base 244a. The main arm 244c is coupled to the body 244b, and is provided to move front and back to the body 244b. The main arm 244c is provided with a plurality of numbers and they are provided to drive separately. The main arms 244c are arranged vertically, i.e., spaced apart from each other along the third direction 16. The main arm 244c used when transferring the substrate W from the buffer unit 220 to the process chamber 260, and the main arm 244c used when transferring the substrate W from the process chamber 260 to the buffer unit 220 may be different.

In the process chamber 260, a substrate treating apparatus 300 which performs a cleaning process to the substrate W is provided. The substrate treating apparatus 300 provided in each process chambers 240 may have different structure based on kinds of cleaning process. The substrate treating apparatus 300 provided in each process chambers 240 may have the same structure. In one embodiment, the process chambers 260 may be divided into a plurality of groups, and the substrate treating apparatus 300 provided in the same group of the process chamber 260 may have the same structure, and the substrate treating apparatus 300 provided in different group of the process chamber 260 may have different structure. For example, when the process chamber 260 is divided into two groups, a first group of the process chambers 260 are provided in one side of the transfer chamber 240, and a second group of the process chambers 260 are provided in the other side of the transfer chamber 240. In one embodiment, a first group of the process chamber 260 and a second group of the process chambers 260 are stacked in this order both in one side and the other side of the transfer chamber 240. The process chambers 260 may be divided into several groups depending on a kinds of chemicals or kinds of cleaning process used.

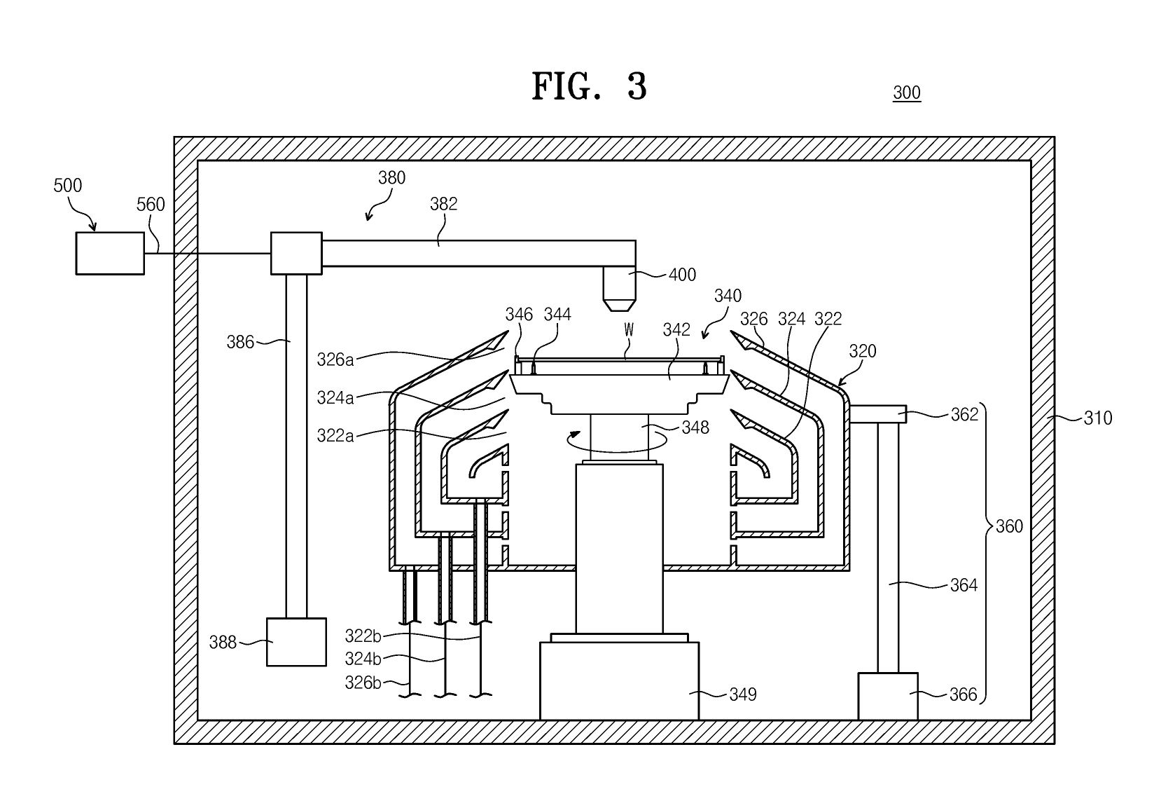

Hereinafter, as an example, a substrate treating apparatus 300 for treating the substrate W will be described. FIG. 3 roughly illustrates a substrate treating apparatus 300 according to an embodiment.

Referring to FIG. 3, the substrate treating apparatus 300 includes a chamber 310, a cup 320, a support unit 340, an elevator unit 360, a discharge unit 380, and a liquid supply unit 500.

The chamber 310 provides a space in its inner side. The cup 320 is placed inside of the chamber 310. The cup 320 provides a treating space where a substrate treating process is performed. The cup 320 has open upper side. The cup 320 includes an inner collecting container 322, a middle collecting container 324, and an outer collecting container 326. Each collecting containers 322, 324, 326 collects a chemical fluid that are different from each other among chemical fluid s used in a process. The inner collecting container 322 is provided as a ring shape surrounding the support unit 340. The middle collecting container 324 is provided as a ring shape surrounding the inner collecting container 322. The outer collecting container 326 is provided as a ring shape surrounding the middle collecting container 324. An inner space 322a of the inner collecting container 322, an interspace 324a between the inner collecting container 322 and the middle collecting container 324, and an interspace 326a between the middle collecting container 324 and the outer collecting container 326 may function as a inlet 410 where chemical fluid flows into the inner collecting container 322, the middle collecting container 324, and the outer collecting container 326, respectively. In the collecting containers 322, 324, 326, collecting lines 322b, 324b, 326b are connected which are extended vertically downward to the bottom, respectively. Collecting lines 322b, 324b, 326b emit the chemical fluid inflow through the collecting containers 322, 324, 326, respectively. The emitted chemical fluid may be reused through a chemical fluid regeneration system (not described) of outside.

The support unit 340 is placed inside of a treating space of the cup 320. The support unit 340 supports the substrate and rotates the substrate during the substrate treating process. The support unit 340 comprises a spin head 342, a supporting pin 344, a chuck pin 346, a driving shaft 348, and a driving unit 349. The spin head 342 has an upper surface usually provided as a circular form, when viewed from a top side. At the bottom of the spin head 342, the driving shaft 348 rotatable by a driving unit 349 is fixedly connected. When the driving shaft 348 rotates, the spin head 342 is rotated. The spin head 342 includes the supporting pin 344 and the chuck pin 346 to support the substrate. The supporting pin 334 is provided with a plurality of numbers. The plurality of supporting pins 334 are spaced apart from each other on edge of the upper surface of the spin head 342 and protrude upward from the spin head 342. The supporting pins 334 are generally arranged to have a ring shape. The supporting pin 334 supports the bottom side of the substrate as to be spaced apart from the upper surface of the spin head 342. The chuck pin 346 is provided as a plurality number. The chuck pin 346 is arranged further apart from a center of the spin head 342 than the supporting pin 34. The chuck pin 346 is provided as to protrude upward from the spin head 342. The chuck pin 346 supports lateral surface of the substrate such that the substrate does not deviate from a right position to a side direction when the support unit 340 is rotating. The chuck pin 346 is provided to move linearly between standby position and supporting position along a radius direction of the spin head 342. The standby position is further apart from a center of the spin head 342 than the supporting position. When loading and unloading the substrate on and from the support unit 340, and when processing the substrate, the chuck pin 346 is placed on the supporting position. The chuck pin 346 on the supporting position is contacted with the lateral part of the substrate.

The elevator unit 360 moves the cup 320 linearly to up and down direction. The elevator unit 360 may move a plurality of collecting containers 322, 324, 326 of the cup 320. Or, even if it is not described, the elevator unit 360 may move the plurality of collecting containers 322, 324, 326, individually. As the cup 320 moves up and down, a height of the cup 320 relative to the support unit 340 is changed. The elevator unit 360 includes a bracket 362, a moving shaft 364, and a driver 366. The bracket 362 is fixedly installed on outer wall of the cup 320. The moving shaft 364 moving up and down direction by the driver 366 is fixedly coupled to the bracket 362. When the substrate W is placed on the support unit 340 or when lifted from the support unit 340, the cup 320 descends such that the support unit 340 protrudes upward from the cup 320. Also, during processing, the height of the cup 320 are controlled such that the chemical fluid flows into the predetermined collecting container 360 depending on a kind of chemical fluid supplied in substrate W. For example, during treating the substrate with the first chemical fluid, the substrate is placed on a height corresponding to the inner space 322a of the inner collecting container 322. Also, when treating the substrate with the second chemical fluid and the third chemical fluid, the substrate is placed on a height corresponding to the interspace 324a between the inner collecting container 322 and the middle collecting container 324, and the interspace 326a between the middle collecting container 324 and the outer collecting container 326, respectively. Unlike described above, the elevator unit 360 may move the support unit 340 up and down direction instead of the cup 320. Also, the cup 320 may include one collecting container 322.

The spray unit 380 supplies a fluid to the substrate W. The fluid may be a chemical fluid. The chemical fluid may include a sulfuric acid. The chemical fluid may include a phosphoric acid. The fluid may be a rinse. The rinse may be pure. The spray unit 380 may be gathered. The spray unit 380 may be provided with one or a plurality of numbers. The spray unit 380 includes a nozzle support 382, a support unit 386, a driver 388, and a nozzle 400. The support unit 386 is provided such that its lengthwise direction is parallel with the third direction 16 and the driver 388 is coupled to the bottom of the support unit 386. The driver 388 rotates and elevates the support unit 386 up and down. The nozzle support 382 is perpendicularly coupled to the support unit 386 at one end that is opposite to the other end to which driver 388 is coupled. The nozzle 400 is installed on bottom the nozzle support 382 at one end that is opposite to the other end to which the support unit 386 is coupled. The nozzle 400 is moved to a processing position and a standby position by the driver 388. The processing position is where the nozzle 400 is located vertically above the cup 320, and the standby position is where the nozzle 400 is out of the vertically above the cup 320.

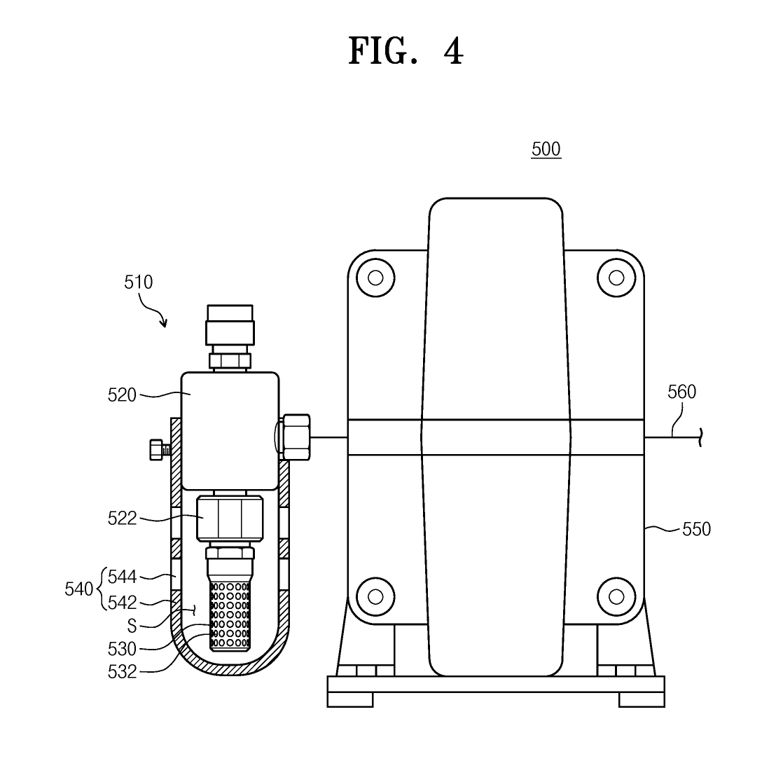

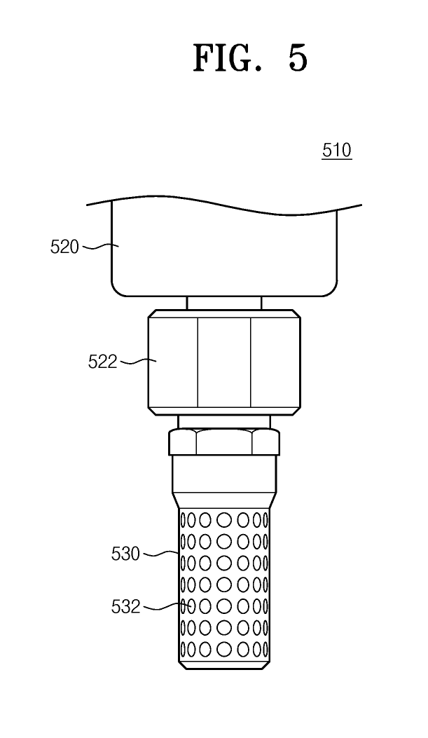

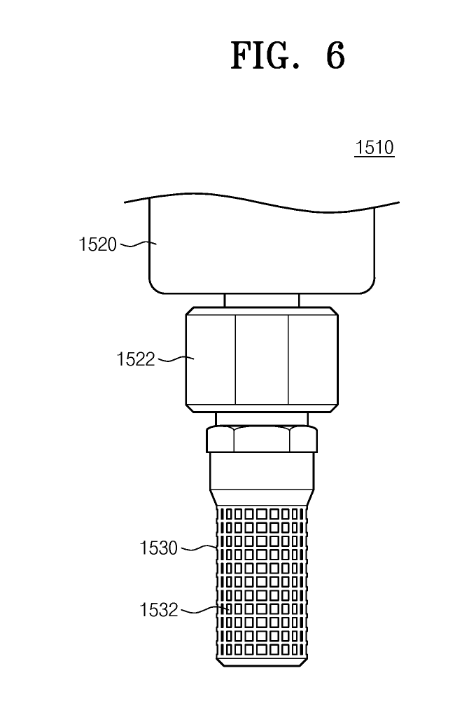

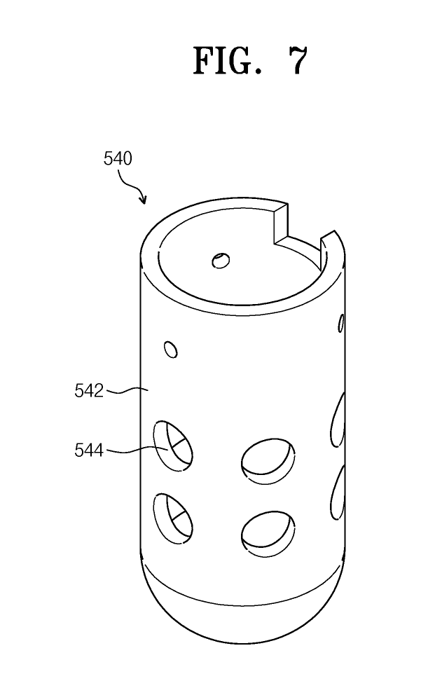

FIG. 4 illustrates a liquid supplying apparatus according to an embodiment. FIGS. 5 and 6 are illustrating a silencer of a pump according to an embodiment. FIG. 7 illustrates a housing of a pump according to an embodiment.

The liquid supply unit 500 includes a storage tank 550, a supply line 560, and a pump 510. The liquid supply unit 500 is used as a liquid supply apparatus 500 according to an embodiment.

The storage tank 550 stores a liquid. The liquid may be a chemical fluid. A stored liquid is supplied to outside through the pump 510. A stored chemical liquid may be supplied to the spray unit 380. The stored chemical liquid is supplied to the spray unit 380 through the supply line 560.

The pump 510 includes a pump body 520, a silencer 530, and a condensation preventing device 540. The pump 510 may be a bellows type.

The pump body 520 is a body of the pump 510. The silencer 530 is connected to the pump body 520. The silencer 530 may be connected to a vent unit 522 of the pump body 520. As described in FIG. 5, a plurality of exhaust holes 532 is formed in a lateral surface of the silencer 530. Or as described in FIG. 6, a lateral surface of the silencer 530 may be formed with a mesh structure. Air flows in the silencer 530. Air comes outside through several exhaust holes 532 formed with a mesh structure.

The condensation preventing device 540 surrounds the silencer 530. The condensation preventing device 540 includes a housing 542.

The housing 542 is connected with the pump body 520. In an example, as shown in FIG. 4, the housing 542 may be formed such that a part of the pump body 520 may be inserted inside. In here, the housing 542 may be a cylinder shape including an opening in upper side. Parts where the pump body 520 and the housing 542 contacted may be firmly adhere and prevent air flow from outside.

Or, although it is not described, there may be an installation unit for connecting the housing 542 with the silencer 530 or the body 520. The installation unit may be provided with any kinds of forms only if the housing 542 is connected to the silencer 530 or the body 520 and may be fixed.

The silencer 530 is placed in the housing 542. The housing 542 is provided to surround the silencer 530. The housing 542 is spaced apart from the silencer 530 and surrounds the silencer 530. The housing 542 is provided with a material having insulation effect. In an example, the housing 542 may be provided with a resin. The housing 542 may be provided with PVC (polyvinyl chloride) or PP (polypropylene).

A plurality of vent holes 544 is formed in a surface of the housing 542. That is, the air came out from the exhaust holes 532 of the silencer 530 is again exhausted to outside through the vent holes 544. The vent hole 544 may be bigger than the exhaust holes 532 formed in the silencer 530. The vent 532 is opposed to the exhaust holes 532. That is, the vent holes 544 are provided in a later surface of the housing 542.

In the state of the housing 542 is coupled to the pump body 520, an upper and a lower sides of the housing 542 is closed. The vent hole 544 may be only formed in the lateral surface of the housing 542. In an example, a lower side of the housing 542 may be closed. That is, outside air may not enter through the lower side of the housing 542.

Also, as described above, an opening may be formed in the upper side of the housing 542. Since the pump body 520 is inserted in the opening, air is not flowed into the housing 542 from an outer top side of the housing 542.

Although it is not described above, when a separate installation unit is provided, top and bottom side of the housing 542 are blocked.

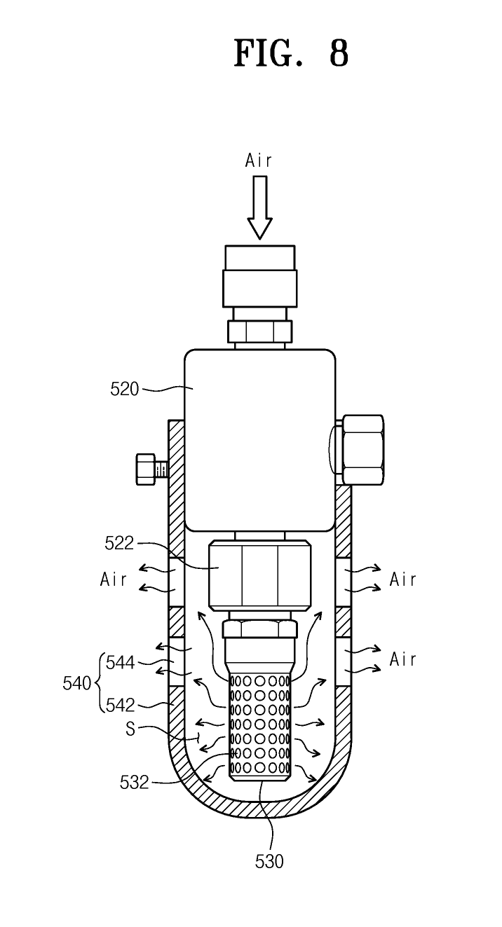

A driving of the pump according to the inventive concept is explained below referring to FIG. 8.

The pump 510 uses a bellows type using air pressure, so the air flows and exhausted thereby providing a power to supply a liquid outside. In the vent unit 522 where the air is exhausted, a silencer 530 is installed. The air flowed into the pump 510 is exhausted to outside through the exhaust holes 532 formed in a surface of the silencer 530 and a vent hole 544 of the housing 542.

When the pump 510 operates, the surface of the silencer 530 is cooled. When the air outside the pump 510 having relatively high temperature flows into the housing 510, condensation or freezing may occur.

However, as described above, upper side of the housing 542 is blocked by coupling to the pump body 520, and a bottom side of the housing 542 is blocked, thereby air flow through both sides of the housing 542 is blocked. Also, in a lateral surface of the housing 542, the air is exhausted through the vent hole 544 thereby amount of air outside flowing through the vent hole 544 is insignificant. To maximize this effect, it is appropriate to make the air exhausted through the exhaust holes 532 of the silencer 530 to be exhausted through the vent hole 544 of the housing 542. Therefore, the vent hole 544 of the housing 542 may be facing the exhaust hole 532 of the silencer 530.

As described above, the housing 542 and the silencer 530 are spaced apart. There is no air flow from the outside and the air exhausted from the silencer 530 is again exhausted through the vent hole 544 passing a separate space S. Therefore, the amount of air staying around the surface of the silencer 530 and the separate space S is insignificant.

Therefore, although the surface of the silencer 530 is cooled, condensation and freezing in the surface of the silencer 530 may be minimized. Also, material of the housing 542 is provided with a resin having high insulating effect, thereby even if the outside of the housing 542 is relatively high temperature, air is not transmitted in the separate space S. Air staying in the separate space S and the temperature of the surface of the silencer 530 are almost similarly maintained. Therefore, condensation and freezing of the surface of the silencer 530 may be prevented.

Meanwhile, the air comes out through the vent hole 544 of the housing 542 adiabatically expands and a surface of the housing 542 is cooled thereby condensation or freezing might happen.

To prevent this, the housing 542 may be provided with a material and thickness having high insulating effect and low heat conductivity. In an example, the housing 542 may be resin. The housing 542 may be PVC and PP. Also, the housing 542 may be provided with appropriate thickness so that condensation and freezing on the surface of the housing 542 may be prevented under operation of silencer 530 and the real pump 510.

Also, to decrease adiabatic expansion and cooling effect of the air which exhausted from the vent hole 544 of the housing 542, the size of the vent hole 544 may be formed appropriately. In an example, the size of the vent hole 544 may be bigger than the exhaust holes 532 formed in a surface of the silencer 530. Thereby, rapid adiabatic expansion of the air may be prevented and the cooling effect of the surface of the housing 542 may be decreased.

In the above described examples, a pump used to supply liquid in the substrate treating apparatus was explained, but it is not limited therein. Therefore, any pump to supply a liquid and a silencer to prevent condensation or freezing is okay.

Foregoing embodiments are examples of the present invention. Further, the above contents merely illustrate and describe preferred embodiments and embodiments may include various combinations, changes, and environments. That is, it will be appreciated by those skilled in the art that substitutions, modifications and changes may be made in these embodiments without departing from the principles and spirit, the scope of which is defined in the appended claims and their equivalents. Further, it is not intended that the scope of this application be limited to these specific embodiments or to their specific features or benefits. Rather, it is intended that the scope of this application be limited solely to the claims which now follow and to their equivalents.

What is claimed is:

1. A pump comprising:
a pump body;
a silencer connected to the pump body; and
a condensation preventing device surrounding the silencer.

2. The pump of claim 1, wherein the condensation preventing device comprises a housing surrounding the silencer, and wherein a plurality of vent holes for exhausting air is formed in the housing.

3. The pump of claim 2, wherein the housing is spaced apart from the silencer surrounds the silencer.

4. The pump of claim 3, wherein a plurality of exhaust holes is formed in a surface of the silencer.

5. The pump of claim 4, wherein the plurality of vent holes is formed in a lateral side of the housing and is opposed to the plurality of exhaust holes.

6. The pump of claim 4, wherein the vent hole is bigger than the exhaust hole.

7. The pump of claim 6, wherein the housing is provided with a resin material.

8. The pump of claim 7, wherein the surface of the silencer is provided with a mesh structure.

9. A liquid supplying apparatus comprising;
a storage tank for storing a liquid; and
a pump for providing a power to supply the liquid to outside,
wherein the pump comprises:
a pump body;
a silencer connected to the pump body; and
a condensation preventing device surrounding the silencer.

10. The liquid supplying apparatus of claim 9, wherein the condensation preventing device comprises a housing surrounding the silencer and wherein a plurality of vent holes for exhausting air is formed in the housing.

11. The liquid supplying apparatus of claim 10, wherein the housing is spaced apart from the silencer surrounds the silencer.

12. The liquid supplying apparatus of claim 11, wherein a plurality of exhaust holes is formed in a surface of the silencer.

13. The liquid supplying apparatus of claim 12, wherein the plurality of vent holes is formed in a lateral side of the housing and is opposed to the plurality of exhaust holes.
